(19) United States
(12) Patent Application Publication
(10) Pub. No.: US 2007/0017903 A1
(43) Pub. Date: Jan. 25, 2007

(54) Method for Treating an Etching Solution

(75) Inventors: Hong Long Change, Hsinchu (TW); Hung Yueh Lu, Hsinchu (TW)

Correspondence Address: OLIFF & BERRIDGE, PLC, P.O. BOX 19928, ALEXANDRIA, VA, 22320, US

(73) Assignee: PROMOS TECHNOLOGIES INC., Hsinchu (TW)

(21) Appl. No.: 11/535,057

(22) Filed: Sep. 25, 2006

Related U.S. Application Data
(62) Division of application No. 10/943,936, filed on Sep. 20, 2004.

(30) Foreign Application Priority Data
May 26, 2004 (TW) 093114904

(51) Int. Cl. C23F 1/00; H01L 21/302

(52) U.S. Cl. 216/93; 438/689

(57) ABSTRACT

The present etching system includes a processing tank with an etching solution containing silicon, a cooling tank, a pre-heating tank, a first pipe for transferring the etching solution from the processing tank to the cooling tank, a second pipe for transferring the etching solution from the cooling tank to the pre-heating tank, and a third pipe for transferring the etching solution from the pre-heating tank to the processing tank. The present method for treating the etching solution first performs an etching process using the etching solution, which is then cooled to a first temperature to form a silicon-saturated etching solution. After silicon-containing particles larger than a predetermined size are filtered out, the silicon-saturated etching solution is heated to a second temperature to form a non-saturated etching solution for repeating the etching process later. The second temperature is preferably at least 10° C. higher than the first temperature.

### BACKGROUND OF THE INVENTION

(A) Field of the Invention

This is a Division of application Ser. No. 10/943,936 filed on Sep. 20, 2004. The disclosure of the prior application is incorporated herein by reference in its entirety.

The present invention relates to a method for treating an etching solution, and more particularly, to a method for treating an etching solution with a stable selectivity between silicon nitride and silicon oxide.

(B) Description of the Related Art

FIG. 1 to FIG. 3 show a method for fabricating a shallow trench isolation on a wafer 10 according to the prior art. The shallow trench isolation is widely used in the fabrication of the metal-oxide-semiconductor (MOS) transistor to form an electrical isolation between transistors. As shown in FIG. 1, the fabrication of the shallow trench isolation begins to form an oxide layer 14, a silicon nitride layer 16 and a photoresist layer 18 in sequence on a silicon substrate 12, and the pattern of the active region 24 is then transformed from an active region mask to the photoresist layer 18.

Referring to FIG. 2, a dry etching process is then performed to remove a portion of the silicon nitride layer 16 and the silicon oxide layer 14 not covered by the photoresist layer 18 from the silicon substrate 12. The dry etching process continues to the etch silicon substrate 12 to form a shallow trench 20 in the silicon substrate 12.

Refer to FIG. 3, after the photoresist layer 18 is removed, a liner oxide layer 22 is formed on the surface of the shallow trench 20 by a thermal oxidation process. Silicon oxide is then deposited in the shallow trench 20 by a chemical vapor deposition (CVD) process, and the surface of the wafer 10 is planarized by a chemical and mechanical polishing (CMP) process. A wet etching process is performed later to remove the silicon nitride layer 16 from the silicon substrate 12 while preserving the silicon oxide layer 14 on the surface of the substrate 12 and silicon oxide in the shallow trench 20. MOS transistors are subsequently formed in the active regions 24 on both sides of the shallow trench 20, and the silicon oxide in shallow trench 20 forms the electrical isolation between MOS transistors.

The conventional method for forming the shallow trench isolation uses a heated phosphoric acid (H₃PO₄) to strip the silicon nitride layer 16. Since subsequent processes to form the MOS transistors are seriously influenced by both the shape and the cleanness of the surface of the wafer 10, it is very important to control the etching selectivity between silicon nitride and silicon oxide. The etching selectivity depends primarily on parameters such as the etchant, reaction products, reaction temperature, reaction time, etc.; therefore, these parameters must be properly controlled to obtain a good etching selectivity.

FIG. 4 shows an etching apparatus 30 according to the prior art. As shown in FIG. 4, the etching apparatus 30 comprises a processing tank 32, a pre-heating tank 34 and an etching solution consisting of phosphoric acid and deionized water. During the etching process, the etching solution in processing tank 32 is heated and maintained at 150° C.˜160° C. to remove the silicon nitride layer 16 from the wafer 10. Phosphoric acid from the facility is pre-heated to 120° C.˜140° C. in the pre-heating tank 34 and then transferred to the processing tank 32 via the pipe 36 to supply the etching solution discharged via the pipeline 38.

FIG. 5 and FIG. 6 show the variation of the silicon concentration of the etching solution in the processing tank 32. As shown in FIG. 5, silicon-containing impurity is generated during the etching reaction of the silicon nitride, and the silicon concentration of the etching solution in the processing tank 32 increases as the processing time of the etching reaction (i.e. reaction time) increases. When the silicon concentration of the etching solution increases continually to a saturation state (about 100 ppm), silicon particles will be generated. The silicon particles will seriously influence the clearness of the etched surface of the wafer 10. For example, a 0.2 μm silicon particle remaining on the surface of wafer 10 will seriously cause integrated circuit fabricated by a 0.13 μm MOS fabrication process to fail.

Referring to FIG. 4, in order to avoid the formation of the silicon particles, the conventional etching apparatus 30 circulates and filtrate the etching solution continually in the processing tank 32 by the pipe 42 and the filter 44 to remove silicon particles therein. However, if there were too many silicon particles, the filter 44 would easily fail due to the blocking of the silicon particles. Therefore, after the etching reaction is performed for certain number of times (i.e. before the silicon concentration reaches 100 ppm), the etching solution in the processing tank 32 must be entirely dumped via the pipe 38, and a completely new etching solution (the silicon concentration is zero) is supplied into the processing tank 32 via the pre-heating tank 34 to prevent the formation of silicon particles due to the silicon saturation of etching solution. Consequently, the variation curve 52 of the silicon concentration of the etching solution in the processing tank 32 presents a zigzag curve between 0 and 100 ppm, as shown in FIG. 5.

The etching selectivity between the silicon nitride and the silicon oxide primarily depends on the silicon concentration of the etching solution. However, the silicon concentration of the etching solution in the processing tank 32 does not maintain at a fixed level, but changes from zero (when a new etching solution is refilled in the processing tank 32) to silicon saturation concentration gradually. Therefore, the etching selectivity between silicon nitride and silicon oxide also changes with the processing time of the etching solution, which further increases the difficulty to control the process parameters, such as the etching time.

According to the treating method currently used in semiconductor fabrication, dummy wafers are used to carry out several dummy runs as the etching solution is renewed entirely (silicon concentration is zero) to increase the silicon concentration of the etching solution to a predetermined level, and the practical etching process of the actual wafer is carried out. However, this treating method obviously reduces the efficiency of the etching solution. Furthermore, completely renewing the phosphoric acid etching solution increases the consumption of phosphoric acid and raises the etching cost.

Please refer to FIG. 6, wherein another conventional method for treating the etching solution periodically drains a portion of the phosphoric acid etching solution via the pipe 38, and supplies an equal amount of new phosphoric acid to the processing tank 32 via the pipe 36. As a result, the variation curve of the silicon concentration of the etching solution in the processing tank 32 has a smaller variation range. Compared with the silicon concentration in the processing tank 32 which changes with the processing time of the etching reaction, phosphoric acid in the pre-heating tank 34 is directly supplied from the facility pipe 140 and the silicon concentration is virtually zero since there is no resource for generating silicon. Therefore, when the etching solution in the processing tank 32 is entirely renewed according to this treating method, it should carry out several dummy runs using the dummy wafers to increase the silicon concentration of the etching solution.

### SUMMARY OF THE INVENTION

The objective of the present invention is to provide a method for treating the etching solution with a stable selectivity between silicon nitride and silicon oxide.

In order to achieve the above-mentioned objective and avoid the problems of the prior art, the present invention provides an etching system and a method for treating the etching solution with a stable selectivity between silicon nitride and silicon oxide. The present etching system comprises a processing tank with an etching solution containing silicon, a cooling tank, a pre-heating tank, a first pipe for transferring the etching solution from the processing tank to the cooling tank, a second pipe for transferring the etching solution from the cooling tank to the pre-heating tank, and a third pipe for transferring the etching solution from the pre-heating tank to the processing tank.

The present method for treating the etching solution first performs an etching process using the etching solution, which is then cooled to a first temperature to form a silicon-saturated etching solution. After silicon-containing particles in the silicon-saturated etching solution larger than a predetermined size are filtered out, the silicon-saturated etching solution is heated to a second temperature to form a non-saturated etching solution for repeating the etching process later. The second temperature is preferably at least 10° C. higher than the first temperature.

Compared with the prior art, the present invention possesses a steadier, smaller variation of the silicon concentration in the etching solution, and achieves a stable etching selectivity between the silicon nitride and silicon oxide. In addition, the present invention need not drain the used etching solution, which can reduce the cost of the etching process dramatically.

### BRIEF DESCRIPTION OF THE DRAWINGS

Other objectives and advantages of the present invention will become apparent upon reading the following description and upon reference to the accompanying drawings in which:

FIG. 1 to FIG. 3 show a method for fabricating a shallow trench isolation on a wafer according to the prior art;

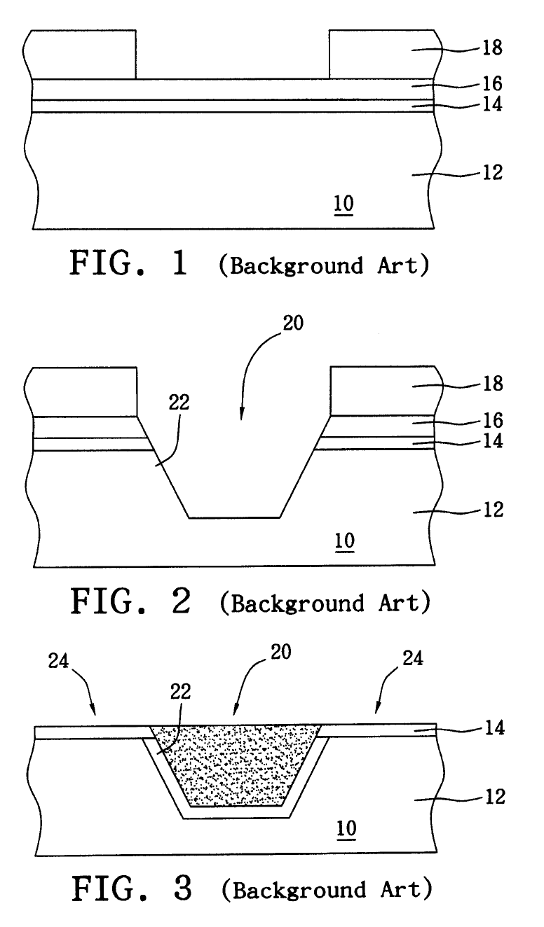

FIG. 4 shows an etching apparatus according to the prior art;

FIG. 5 and FIG. 6 show the variation of the silicon concentration of the etching solution in the processing tank;

FIG. 7 shows the relation of the silicon concentration in the etching solution with respect to both the etching rate and silicon particle concentration;

FIG. 8 shows the relation between the silicon saturation concentration of the etching solution and the temperature;

FIG. 9 illustrates an etching system according to the present invention; and

FIG. 10 shows the variation of the silicon concentration of the etching solution in the processing tank.

### DETAILED DESCRIPTION OF THE INVENTION

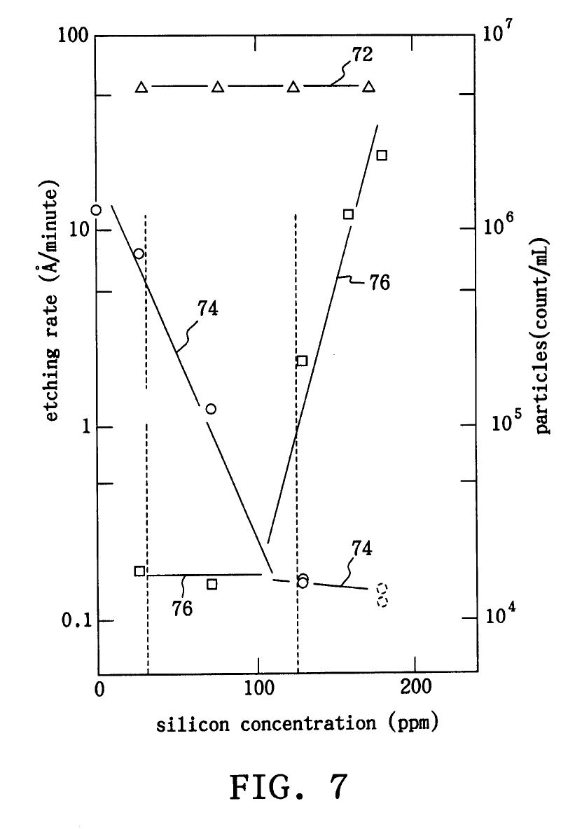

FIG. 7 shows the relation between the silicon concentration and both the etching rate and silicon particle concentration in the etching solution. Curve 72 represents the etching curve of silicon nitride, curve 74 represents the etching curve of silicon oxide, and curve 76 is a variation curve of the silicon particle concentration. As shown in FIG. 7, the etching rate of silicon nitride is substantially not influenced by the silicon concentration virtually and is fixed at about 90 Å/min. In contrary, the etching rate of silicon oxide reduces as the silicon concentration increases, and is fixed at about 0.2 Å/min as the silicon concentration is above 100 ppm. When the silicon concentration is above 100 ppm, the silicon particle concentration of the etching solution increases as the silicon concentration increases.

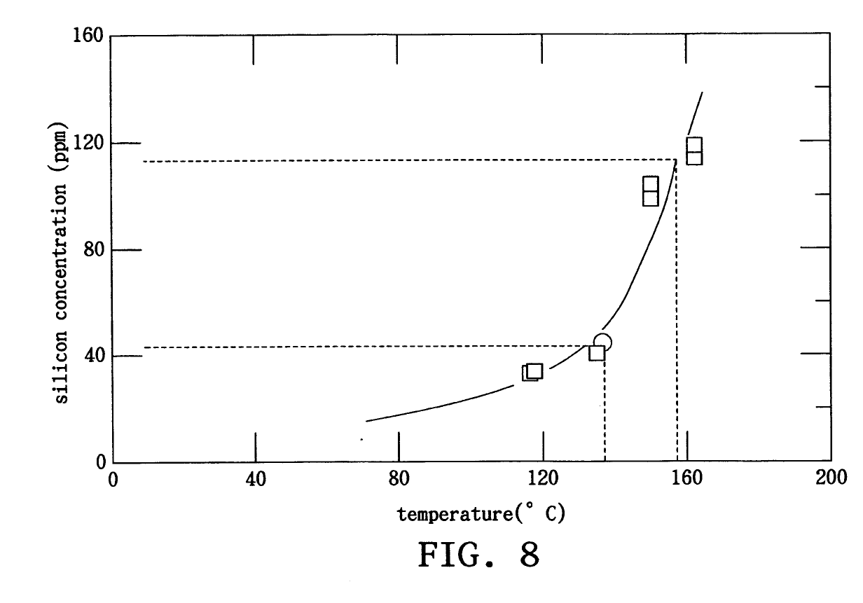

FIG. 8 shows the relation between the silicon saturation concentration of the etching solution (i.e. the solubility of silicon in the etching solution) and the temperature. As shown in FIG. 8, the silicon saturation concentration is about 20 ppm at 10° C., 40 ppm at 120° C., and 120 ppm at 160° C. That is, increasing the temperature of the etching solution will increase the solubility of silicon in the etching solution. In contrary, decreasing the temperature of the etching solution can force silicon in the etching solution to form silicon particles (solid phase) and reduce the silicon concentration of the etching solution (liquid phase), wherein silicon particles in solid phase can be filtrated via a filter and removed from the etching solution.

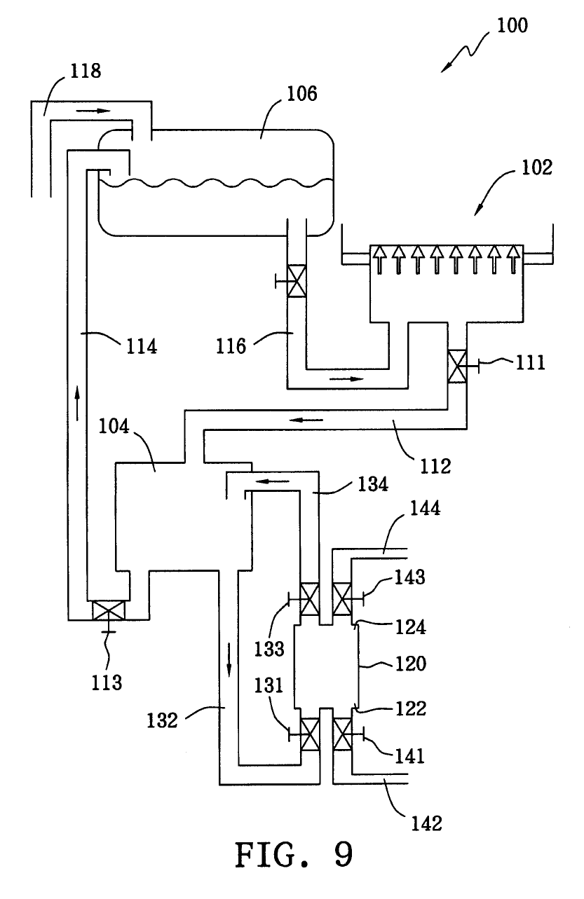

FIG. 9 illustrates an etching system 100 according to the present invention. As shown in FIG. 9, the etching system 100 comprises a processing tank 102 with an etching solution containing silicon, a cooling tank 104, a pre-heating tank 106, a pipe 112 for transferring the etching solution from the processing tank 102 to the cooling tank 104, a pipe 114 for transferring the etching solution from the cooling tank 104 to the pre-heating tank 106, and a pipe 116 for transferring the etching solution from the pre-heating tank 106 to the processing tank 102. In addition, the pre-heating tank 106 can derive a new etching solution from a facility pipe 118.

The etching solution is cooled to a first temperature in the cooling tank 104, and the silicon concentration of the etching solution is saturated at the first temperature, wherein the first temperature is preferably between 80° C. and 120° C. The etching solution is then heated to a second temperature in the pre-heating tank 106, and the silicon concentration of the etching solution is not saturated at the second temperature, wherein the second temperature is preferably at least 10° C. higher than the first temperature. The etching solution from the cooling tank 104 is heated in the pre-heating tank 106, and then transferred to the processing tank 102 via the pipe 116 to carry out a wet etching process. The temperature of the etching solution in the processing tank 102 can be between 130° C. and 160° C. Preferably, the etching solution is heated in the pre-heating tank 106 directly to the temperature at which the etching reaction is to be carried out, and then transferred to processing tank 102 via the pipe 116.

The present etching system 100 can further comprise a filter 120 with an inlet 122 and an outlet 124, a pipe 132 for transferring the etching solution from the bottom of the cooling tank 10 to the inlet 122, and a pipe 134 for transferring the etching solution from the outlet 124 to the cooling tank 104. The filter 120 has a plurality of openings with a size smaller than 0.1 μm. The cooling tank 104 forces silicon in the etching solution to form solid silicon particles by reducing the temperature of the etching solution. The solid silicon particle larger than 0.1 μm will be filtered from the etching solution since it cannot pass through the openings of the filter 120 as the etching solution is passing through the filter 120 in a downstream manner.

The present etching system 100 can further comprise a pipe 142 connected to the inlet 122 and a pipe 144 connected to the outlet 124. Since the openings of the filter 120 might be blocked by the silicon particles, the blocked silicon particles must be cleaned and removed frequently to maintain the filtration function of the filter 120. According to the present invention, a solution containing hydrofluoric acid (for example, a diluted hydrofluoric acid) can be transferred in a downstream manner from the pipe 142 to the filter 120 to dissolve the silicon particles on the filter 120, and the dissolved silicon particles can then be delivered out of the filter 120 from the pipe 144. The hydrofluoric acid remained on the filter 120 is then washed by deionized water. In addition, deionized water can be input via the pipe 144 to clean and remove the silicon particles on the filter 120 in an upstream manner, and waste liquid is discarded out of the filter 120 from the pipe 142.

The valves 131, 133 are closed on cleaning the filter 120 to prevent silicon particles on the filter 120 from flowing back to the cooling tank 104. When the filter 120 is filtrating silicon particles in the cooling tank 104, the valves 141, 143 are close. Furthermore, the valve 113 can be closed during the cleaning of the filter 120 to temporarily stop supplying etching solution to the pre-heating tank 106. Since the pre-heating tank 106 stores some etching solution, the etching solution can be continuously supplied to the processing tank 102 during the cleaning of the filter 120. After the filter 120 is cleaned and the silicon particles in the cooling tank 104 are filtrated, the valve 113 is opened to supply the etching solution to the pre-heating tank 106.

As the design rule of the semiconductor fabrication shrinks, the allowed particle size in etching solution decreases correspondingly. The filter 120 with smaller openings must be used (for example, an opening smaller than 0.1 μm). However, a smaller opening could easily fail due to the blocking of particles, and thus the filter 120 must be cleaned or replaced more frequently to ensure the filtrating and removing of the particles from the etching solution. During cleaning or replacing of the filter 120, the pre-heating tank 106 can also supply continuously filter-treated etching solution to the processing tank 102 according to the present invention. In other word, the present invention can increase cleaning frequency of the filter 120 without influencing the supply of the etching solution. Consequently, the filter 120 with smaller openings can be used in the future semiconductor fabrication process.

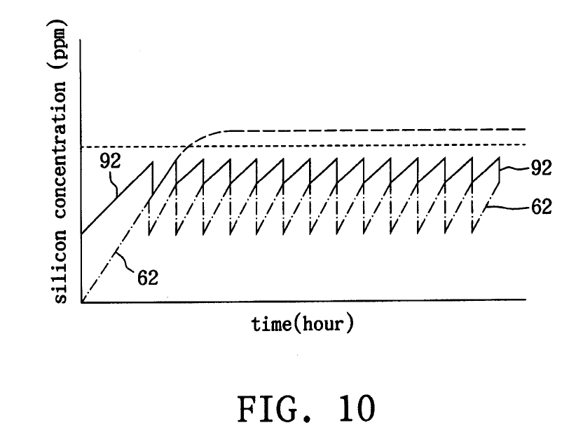

FIG. 10 shows the variation of the silicon concentration of the etching solution in the processing tank 102. The present invention controls the temperature of the cooling tank 104 to indirectly control the silicon concentration of the etching solution in the processing tank 102. The silicon concentration of the etching solution in the cooling tank 104 is saturated, and the saturated concentration is determined by the temperature of the cooling tank 104. Without a new etching solution delivered into the pre-heating tank 106 from the facility pipe 118, the pre-heating tank 106 only heats the etching solution from the cooling tank 104 and the silicon concentration of the etching solution is not changed. The silicon concentration of the etching solution from the pre-heating tank 106 to the processing tank 102 is maintained at a predetermined level, rather than zero silicon concentration.

Compared with the etching solution with a zero silicon concentration added into the processing tank 32, thus causing larger concentration variation according to the prior art (as shown in the curve 62 in FIG. 10), the silicon concentration of the etching solution added into processing tank 102 is not zero and the variation curve 92 of the silicon concentration has smaller concentration variation according to the present invention. For the present etching system 100, the etching solution can even be input into or output from the processing tank 102 in a successive manner with a predetermined flow rate, and the variation curve of the silicon concentration becomes steadier and smaller than the saturation concentration.

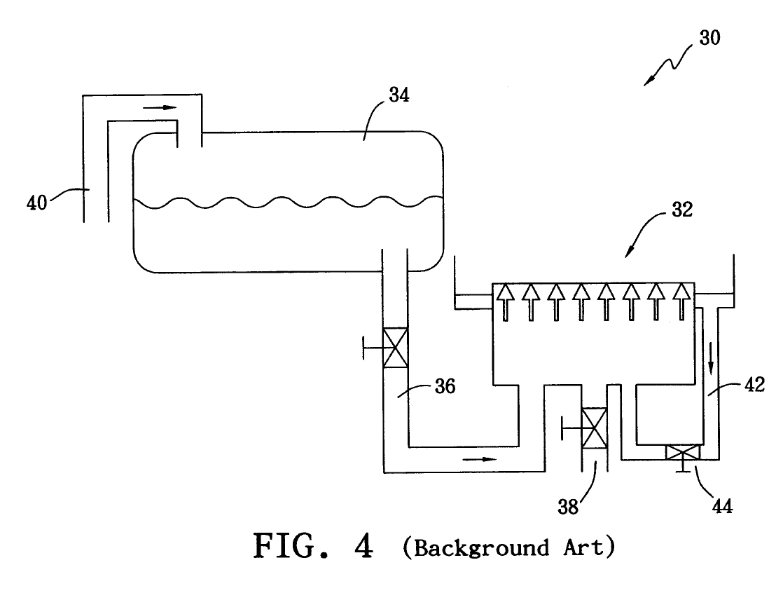

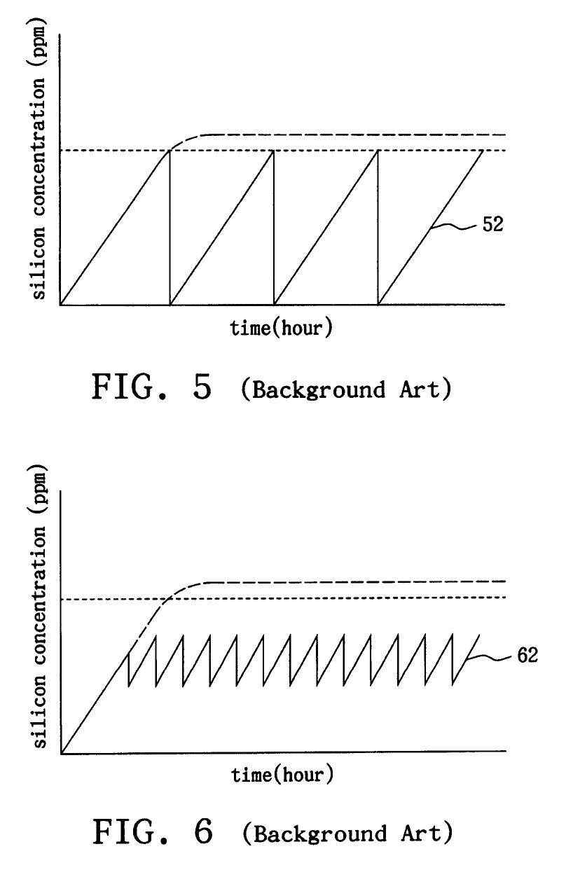

Furthermore, compared with the prior art with a zero silicon concentration of etching solution in the pre-heating tank 34 (see FIGS. 4, 5 and 6), where the etching solution in the processing tank 32 must be periodically exchanged, the present invention does not need to carry out the dummy runs in the processing tank 102 since the silicon concentration of the etching solution in the pre-heating tank 106 is not zero. The cooling tank 104 can supply the recycled etching solution to the pre-heating tank 106; therefore the silicon concentration of the etching solution in the pre-heating tank 106 is not zero.

In addition, phosphoric acid is only used as a catalyst in the etching solution, which does not be consumed in theory when the etching reaction carries on. However, the used etching solution must be drained, which will increase the cost of the etching process and raise the additional cost on treating etching waste liquid according to the prior art. In contrary, the present invention need not drain the used etching solution, which can reduce the cost of the etching process dramatically.

Briefly, the present method for treating the etching solution uses an etching solution to perform an etching process to a silicon-containing film, and the etching solution is then cooled to 80° C.˜120° C. to form an etching solution with a silicon concentration at a saturated state. After silicon particles larger than a predetermined size (for example, 0.1 μm) are filtrated and removed from the saturated etching solution, the saturated etching solution is heated up at least 10° C. to form a non-saturated etching solution, which is then used to repeat the etching process.

The above-described embodiments of the present invention are intended to be illustrative only. Numerous alternative embodiments may be devised by those skilled in the art without departing from the scope of the following claims.

What is claimed is:

1. A method for treating an etching solution, comprising steps of:
performing an etching process for stripping a silicon nitride film with an etching solution including phosphoric acid;
cooling the etching solution to a first temperature between 80° C. and 120° C., and the silicon concentration of the etching solution being saturated at the first temperature to form a silicon-saturated etching solution;
filtrating silicon particles larger than a predetermined size from the silicon-saturated etching solution;
heating the silicon-saturated etching solution to a second temperature to form a non-saturated etching solution; and
repeating the etching process with the non-saturated etching solution.

2. The method for treating an etching solution of claim 1, wherein the second temperature is at least 10° C. higher than the first temperature.

3. The method for treating an etching solution of claim 1, wherein the step of filtrating silicon particles is performed by passing the silicon-saturated etching solution in a downstream manner through a filter with a plurality of openings smaller than 0.1 μm to remove silicon particles larger than the openings from the etching solution.

4. The method for treating an etching solution of claim 3, further comprising a step of passing a deionized water in an upstream manner through the filter to remove silicon particles therefrom.

5. The method for treating an etching solution of claim 3, further comprising a step of passing a solution containing hydrofluoric acid in the downstream manner through the filter to remove silicon particles therefrom.

6. The method for treating an etching solution of claim 1, wherein the etching process is performed at the second temperature.
